(19) United States
(12) Patent Application Publication
(10) Pub. No.: US 2015/0173200 A1
(43) Pub. Date: Jun. 18, 2015

(54) METHOD OF FORMING METAL LINES HAVING HIGH CONDUCTIVITY USING METAL NANOPARTICLE INK ON FLEXIBLE SUBSTRATE

(71) Applicant: KYUNGPOOK NATIONAL UNIVERSITY INDUSTRY-ACADEMIC COOPERATION FOUNDATION, Daegu (KR)

(72) Inventors: Hak-Rin KIM, Daegu (KR); Jin-Hyuk BAE, Daegu (KR); Ji-Sub PARK, Gumi-si (KR)

(21) Appl. No.: 14/564,382

(22) Filed: Dec. 9, 2014

(30) Foreign Application Priority Data
Dec. 16, 2013 (KR) 10-2013-0156505

(51) Int. Cl. H05K 3/00; H05K 3/12

(52) U.S. Cl. CPC H05K 3/007; H05K 3/1291; H05K 2203/06; H05K 2203/1131

(57) ABSTRACT

Provided is a method of forming metal-lines having high conductivity on a flexible substrate, including (a) forming a buffer layer on a first substrate, (b) forming metal-lines by printing a metal-nanoparticle-ink on the buffer layer, (c) sintering the metal-nanoparticle-ink through thermal treatment, (d) forming supporting-members between the metal-lines and the first substrate by etching the buffer layer by using a etching solvent and controlling an etching time so that a portion of the buffer layer is not etched, (e) picking up the metal-lines from the first substrate by using a stamp in the state where a pattern of the metal-lines is fixed and arranged by the supporting-members, and (f) transferring the picked-up metal-lines to a second substrate, wherein the first substrate is a heat resistant substrate which is not deformed at a sintering temperature of the metal-nanoparticle-ink, and the second substrate is a flexible substrate.

This application claims priority to Korean Patent Application No. 10-2013-0156505, filed on Dec. 16, 2013, and all the benefits accruing therefrom under 35 U.S.C. §119, the contents of which in its entirety are hereby incorporated by reference.

### BACKGROUND OF THE INVENTION

1. Field of the Invention

The present invention relates to a method of forming metal lines on a flexible substrate, and more particularly, to a method of forming metal lines having high conductivity on a flexible substrate by forming the metal lines by printing a metal nanoparticle ink on a heat resistant substrate, by performing a thermal treatment/sintering process at a high temperature to allow the metal lines to have a high conductivity characteristic, and after that, by transfer-printing the metal lines on the flexible substrate.

2. Description of the Prior Art

Recently, with increasing expectations and demands for flexible electronic devices, much attention has been drawn by a technique suitable for mass production due to inexpensive production costs, low process restrictions according to use of a flexible film substrate, and a shortened process time in comparison with an existing process using photolithography. Therefore, recently, manufacturing electronic devices through various printing techniques, for example, a so-called “direct printing” process such as screen printing, inkjet printing, or gravure printing has been actively researched.

In this regard, a metal nanoparticle ink which is used to form essential conductive metal lines for manufacturing the electronic devices has also been actively researched. In the related art, in order to form the metal lines, a deposition or etching process is essentially used. However, in the case of forming the metal lines by using the metal nanoparticle ink, since the metal lines can be formed through a direct printing process, the process time is shortened, and a vacuum state is unnecessary in the process. Therefore, the production cost can be reduced. Accordingly, the forming the metal line by using the metal nanoparticle ink can be applied to large-sized products and to fields of manufacturing flexible electronic devices using a flexible substrate.

As the metal nanoparticle ink, metal nanoparticles are mainly used. The aforementioned metal nanoparticles have advantages as follows. The metal nanoparticles can be dispersed in a solvent so as to form an ink. Due to the metal nanoparticles, metal line electrodes can be formed with high resolution. Since the metal nanoparticles have a small particle size, high density can be obtained. In comparison with the case of using a conductive polymer based ink, an excellent conductivity characteristic can be expected. Due to the small particle size, sintering can be performed at a relatively low temperature for a short time due to a thermodynamic size effect.

On the other hand, the metal nanoparticle ink is manufactured by dispersing metal nanoparticles, that is, metal particles having a nano size in the solvent. The metal nanoparticles are dispersed in a very unstable state. Therefore, although the metal particles are dispersed in the solvent at the first stage, the metal nanoparticles are aggregated in a short time. Because of the aggregation, in the case of forming the metal line electrodes through the printing process, there is a problem in that a uniformity characteristic and a conductivity characteristic become bad and process reproducibility becomes low.

As a representative method of manufacturing the metal nanoparticle ink proposed in order to solve this problem, there is a “steric stabilization” method capable of improving dispersion stability by preventing aggregation of metal nanoparticles by coating surfaces of the metal nanoparticles with a material for enhancing a degree of dispersion to a solvent. In addition, there is a method of adding a surfactant in order to improve the dispersion stability. However, since most of the materials of enhancing the degree of dispersion or the surfactants have an insulating property, in the state where the metal line electrode is formed by using these materials, the conductivity characteristic becomes very bad because of the insulating property of the aforementioned materials arranged between the metal nanoparticles. In addition, since a cross-linking material mixed in order to derive the thin film formed through a printing process so as to have a stable adhesion characteristic on the substrate and in order to prevent crack and deformation of the thin film is also a material having an insulating property, there is a problem in that the metal line electrode has a bad conductivity characteristic because of the material having an insulating property. Various researches have been made in order to solve this problem. The most appropriate method is a sintering process. Sintering denotes a phenomenon where power particles are combined to be aggregated when strong external energy is applied to the powder. In the case of the metal nanoparticle ink configured with the metal nanoparticles, the metal nanoparticles are simply combined through the sintering process to have an enlarged particle size, so that an ideal thin film having no pore is obtained. In addition, since a material which is coated on the surfaces of the metal nanoparticles in order to improve the dispersion stability is dissolved to disappear, the conductivity characteristic can be maximized.

FIG. 1 is a conceptual diagram illustrating a process of sintering the metal nanoparticles of the metal nanoparticle ink. As illustrated in FIG. 1, polymers which are coated through the sintering process are dissolved to disappear, and the metal nanoparticles are combined to be aggregated, so that the metal lines having a high conductivity characteristic can be formed.

As the most representative sintering method, there is a sintering method of performing thermal treatment on the ink printed on the substrate by using an oven or a furnace. The thermal treatment/sintering method has advantages in that the process is simple as a very basic treatment method and a good conductivity characteristic can be obtained. However, in the thermal treatment/sintering method, the thermal treatment at a high temperature of 150° C. to 300° C. is necessary although it is different according to the type of the material. In addition, in the state where the thermal treatment/sintering method is applied to flexible electronic devices, in most of the film substrate which is to be used as the substrate, the substrate is deformed at a temperature lower than the sintering temperature. As the representative deforming temperatures of the film substrate, the deforming temperature of PET is 120° C., the deforming temperature of PEN is 180° C., and the deforming temperature of PI is 300° C. Therefore, there is a problem in selection of the substrate used for obtaining the metal lines having a good conductivity characteristic by using the thermal treatment/sintering method on the flexible film substrate.

Various researches have been made in order to solve the problems of the thermal treatment/sintering method and to form the thin film of the metal nanoparticle ink having a high conductivity characteristic on the flexible film substrate. Representatively, a change of composition conditions for the metal nanoparticle ink and a new type of the sintering method have been proposed. First, with respect to the change of composition conditions of the ink, there is a method of lowering a melting temperature of the metal nanoparticles by reducing the particle size of the metal nanoparticles. In addition, there is a method capable of sintering at a lower temperature than that of the existing method by dissolving the dispersant or the cross-linking material coated on the metal nanoparticles at a low temperature in order to secure the dispersion stability of the metal nanoparticles and the thin film formation stability or by optimizing the mixture ratio so as to be suitable for a low temperature process. However, in the above-described method, since the size of the metal nanoparticles is already sufficiently small, there is a limitation in further reducing the size. It is difficult to select new types of the dispersant and the cross-linking agent material which are optimized for manufacturing the ink having good dispersion stability, and it is also difficult to optimize the formation conditions for the thin film having high conductivity.

On the other hand, in the state where a metal nanoparticle ink is printed on an arbitrary substrate and, after that, sintering is performed, metal nanoparticles constituting the metal nanoparticle ink are combined, and the conductivity characteristic of metal lines is improved by a cross-linking agent for improving an adhesion force between a thin film and a substrate. In addition, the metal lines are also combined with the substrate, so that an adhesion force between the metal nanoparticle ink based metal lines and the substrate is also increased.

Therefore, in the state where the metal lines are formed by using the metal nanoparticle ink through thermal treatment/sintering process at a high temperature, the adhesion force between the metal nanoparticle ink and the substrate is increased by the sintering, so that there is a problem in that it is difficult to pick up the metal nanoparticle ink by using a stamp through a typical transfer printing method.

### SUMMARY OF THE INVENTION

The present invention is to provide a method of forming highly-conductive metal lines on a flexible substrate by using a metal nanoparticle ink.

The present invention is also to enable a thermal treatment/sintering process at a high temperature on a metal nanoparticle ink in order to manufacture metal nanoparticle ink based metal lines having a high conductivity characteristic on a flexible substrate.

The present invention is also to prevent a pick-up yield from being decreased according to improvement of a characteristic of adhesion between metal lines and a glass substrate due to a cross-linking agent added to a metal nanoparticle ink in a transfer process for the metal lines.

The present invention is also to partially form supporting members between metal lines and a glass substrate through a printing process in order to improve a pick-up yield of the metal lines from the glass substrate, wherein the supporting members is formed through the printing process and is manufactured by partially etching a buffer layer through wet etching.

The present invention is also to prevent metal lines from being peeled off due to a weak adhesion force between the metal lines and a film when the metal lines are printed on a flexible substrate.

The present invention is also to prevent a shape and position of a pattern of metal lines from being changed due to formation of fine supporting members through etching of a buffer layer.

According to a first aspect of the present invention, there is provided a method of forming metal lines having high conductivity on a flexible substrate including (a) forming a buffer layer on a first substrate, (b) forming metal lines by printing a metal nanoparticle ink on a surface of the buffer layer, (c) sintering the metal nanoparticle ink through thermal treatment to improve the conductivity of the metal lines, (d) forming supporting members between the metal lines and the first substrate by etching the buffer layer by using a buffer layer etching solvent and by controlling an etching time so that a portion of the buffer layer is not etched, (e) picking up the metal lines from the first substrate by using a stamp in the state where a pattern of the metal lines is fixed and arranged by the supporting members, and (f) transferring the picked-up metal lines to a second substrate, wherein the first substrate is a heat resistant substrate which is not deformed at a sintering temperature of the metal nanoparticle ink, and the second substrate is a flexible substrate.

According to a second aspect of the present invention, there is provided a method of forming metal lines having high conductivity on a flexible substrate including (a) forming a buffer layer on a first substrate, (b) forming metal lines by printing a metal nanoparticle ink on a surface of the buffer layer, (c) partially curing the buffer layer through primary thermal treatment, (d) forming supporting members between the metal lines and the first substrate by etching the buffer layer by using a buffer layer etching solvent and by controlling an etching time so that a portion of the buffer layer is not etched, (e) sintering the metal nanoparticle ink through secondary thermal treatment to improve the conductivity of the metal lines, (f) picking up the metal lines from the first substrate by using a stamp in the state where a pattern of the metal lines is fixed and arranged by the supporting members; and (g) transferring the picked-up metal lines to a second substrate, wherein the first substrate is a heat resistant substrate which is not deformed at a sintering temperature of the metal nanoparticle ink, and the second substrate is a flexible substrate.

In the above aspect of the present invention, in order to pick up the metal lines from the flexible substrate, it is preferable that the supporting members are destructed by applying a pressure by which the supporting members are able to be destructed by the stamp in the state where a pattern of the metal lines is arranged and retained by the supporting members, and the metal lines detached from the supporting members are picked up due to the destruction of the supporting members by using the stamp, or it is preferable that a contact area between the metal lines and the supporting members is adjusted by controlling a buffer layer etching condition, so that first adhesion energy of a contact surface between the stamp and the metal lines and second adhesion energy of a contact surface between the metal lines and the supporting members are adjusted, and the metal lines are picked up. In other words, in order to optimize a transfer condition, it is preferable that the contact area between the stamp and the metal lines, the contact area between the metal lines and the supporting members, a pick-up speed of the stamp are optimized.

According to a method of forming metal lines according to the present invention, after metal lines using a metal nanoparticle ink is formed on a substrate having high heat resistance, a thermal treatment/sintering process is performed at a high temperature, and the metal lines are transfer-printed on a flexible substrate, so that it is possible to perform the thermal treatment/sintering process on the metal nanoparticle ink at a high temperature. As a result, it is possible to form the metal lines having high conductivity on the flexible substrate.

In addition, according to a method of forming metal lines according to the present invention, a buffer layer is formed, and supporting members are formed between a substrate and metal lines by etching the buffer layer so as for a portion of the buffer layer to remain, so that the picking-up by the stamp is facilitate, and a transfer printing process can be applied in the state where a shape of a pattern can be maintained.

In addition, according to a method of forming metal lines according to the present invention, in addition to the metal lines, the buffer layer used for improving the pick-up yield is also formed through a printing process, so that it is possible to implement a simple process with low cost.

In addition, according to a method of forming metal lines according to the present invention, a stamp having a patterned mold is used, so that it is possible to repetitively perform transfer printing, and it is possible to form a mesh structure of stacked metal lines by repetitively performing the transfer printing.

In addition, according to a method of forming metal lines according to the present invention, an adhesive layer is formed between the metal lines and the flexible substrate, so that it is possible to prevent occurrence of a thin film peeling-off phenomenon where the highly-conductive metal lines are peeled off from the flexible substrate because of bending or the like.

### BRIEF DESCRIPTION OF THE DRAWINGS

The above and other objects, advantages and features of the present invention will become more fully understood from the detailed description given hereinbelow and the appended drawings which are given by way of illustration only, and thus are not intended as a definition of the limits of the present invention, and wherein:

FIG. 1 is a conceptual diagram illustrating a process of sintering metal nanoparticles of a metal nanoparticle ink;

FIG. 2 is a diagram illustrating a sequence of processes of a metal line forming method according to an exemplary first embodiment of the present invention;

FIG. 3 is a diagram illustrating a graph of resistivity for explaining a conductivity characteristic of a metal nanoparticle ink according to a thermal treatment/sintering temperature and a change of characteristics of a thin film according to an organic buffer layer wet etching process for forming supporting members in a highly-conductive metal line forming method according to the first embodiment of the present invention;

FIG. 4 is a conceptual cross-sectional diagram illustrating a process of picking up a highly-conductive metal electrode pattern formed on the supporting members by using a flat stamp in the metal line forming method according to the first embodiment of the present invention;

FIG. 5 is conceptual cross-sectional diagram illustrating a process of selectively picking up a highly conductive metal electrode pattern formed on the supporting members by using a stamp having a patterned mold in a metal line forming method according to the third embodiment of the present invention;

FIGS. 6A and 6B are cross-sectional diagrams and plan diagrams illustrating a mesh-shaped stack structure which formed by repetitively performing the transfer printing by using the stamp while changing the printing direction by 90 degrees in the metal line forming method according to the present invention;

FIGS. 7A and 7B are pictures of test of stability with respect to bending according to existence of an adhesive layer in the metal line forming method according to the present invention;

FIG. 8 is a diagram illustrating a sequence of processes of a metal line forming method according to a second embodiment of the present invention;

FIG. 9 is pictures illustrating a change of the supporting members according to the etching time with respect to the buffer layer and the contact area between the metal lines and the supporting members in the metal line forming method according to the second embodiment of the present invention;

FIGS. 10 and 11 are diagrams illustrating pictures of the surface of the stamp on which the metal lines are picked up for explaining the pick-up yield according to the buffer layer etching times of the metal lines having different line widths in the metal line forming method according to the second embodiment of the present invention; and

FIG. 12 is a graph illustrating a pick-up yield of the metal lines according to the buffer layer etching time in the metal line forming method according to the second embodiment of the present invention.

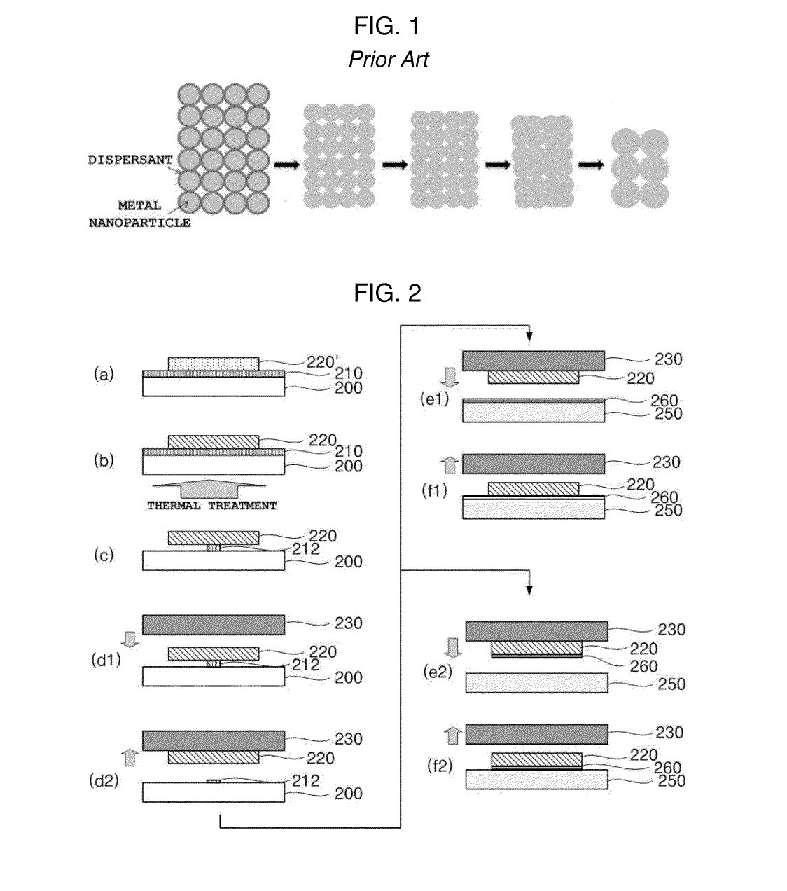

### DESCRIPTION OF THE PREFERRED EMBODIMENT

In a metal line forming method according to the present invention, metal lines are formed by printing a metal nanoparticle ink on a heat resistant substrate, and after that, the metal lines are transferred on a flexible substrate, so that highly-conductive metal lines are formed on the flexible substrate.

### First Embodiment

Hereinafter, a metal line forming method according to an exemplary first embodiment of the present invention will be described in detail with reference to the attached drawings. FIG. 2 is a diagram illustrating a sequence of processes of the metal line forming method according to the first embodiment.

Referring to (a) of FIG. 2, in the metal line forming method according to the first embodiment of the present invention, first, a buffer layer 210 is formed on a first substrate 200, and after that, metal lines are formed by printing a metal nanoparticle ink 220 over the buffer layer.

The buffer layer 210 may be formed by using a solution having low viscosity and low surface tension and containing fluorochemical acrylic polymers in a hydrofluoroether solvent or a material which is processable in a printing process and an additional etching process. The buffer layer may be formed by using, for example, NOVEC™ 1700 Electronic Grade Coating” (trade name, produced by 3M™).

Similarly to the metal nanoparticle ink, the buffer layer may be formed by using a printing process. As the printing for forming the buffer layer and the metal nanoparticle ink, all types of direct printing are available. In the case of the buffer layer, spin coating, bar coating, dip coating, or the like may be used. In the case of the metal nanoparticle ink, screen printing, inkjet printing, gravure printing, or the like may be used.

As the first substrate 200, a substrate which has excellent thermal conductivity and heat resistance and is not deformed at a temperature where the metal nanoparticle ink is subjected to thermal treatment/sintering is preferred. As the first substrate, a glass, a silicon wafer, a ceramic, or the like may be used.

The metal nanoparticle ink is an ink where metal nanoparticles coated by a dispersant are dispersed in a solvent. The metal nanoparticle ink with a predetermined pattern is printed on a surface of the buffer layer. The metal nanoparticles may be, for example, Au, Ag, Cu, Ni, or the like.

Next, referring to (b) of FIG. 2, the metal nanoparticle ink is sintered through high-temperature thermal treatment, so that the conductivity of the metal lines 220 is improved. The thermal treatment/sintering process is performed at a temperature of about 150° C. to 300° C.

Next, referring to (C) of FIG. 2, after the above-described thermal treatment/sintering process, the resulting product is immersed into a buffer layer etching solution, and the buffer layer is etched by wet etching. At this time, an etching time is controlled so that a portion of the buffer layer is not etched. Due to the non-etched portion of the buffer layer, supporting members 212 are formed between the metal lines 220 and the first substrate. Therefore, the pattern shape of the metal lines is maintained even after the etching process and a transfer process, and a pick-up process is facilitated.

The buffer layer etching solution needs to be a material which reacts with only the buffer layer so as to etch only the buffer layer without affecting the metal nanoparticle ink. In addition, the buffer layer etching solution needs to be a material which effectively dissolves the buffer layer even after a thermal treatment/sintering at a high temperature. On the other hand, in the embodiment, in the state where “NOVEC™ 1700 Electronic Grade Coating” (trade name, produced by 3M™) is used as the aforementioned buffer layer, as a solvent for etching the buffer layer, methoxy-nonafluorobutane (C₄F₉OCH₃) may be used, and for example, “NOVEC™ 7100 Engineered Fluid” (trade name, produced by 3M™) may be used.

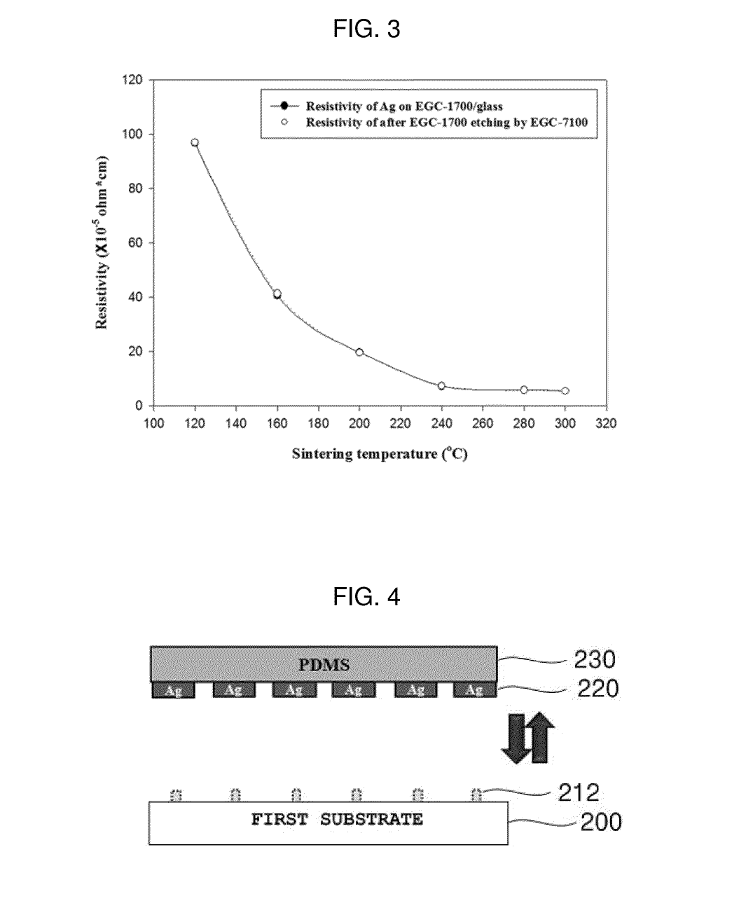

FIG. 3 is a diagram illustrating a graph of resistivity for explaining a conductivity characteristic of the metal nanoparticle ink according to a thermal treatment/sintering temperature in the highly-conductive metal line forming method according to the first embodiment of the present invention. In FIG. 3, the symbol “” indicates a conductivity characteristic of the metal nanoparticle ink on the buffer layer according to the thermal treatment/sintering temperature, the symbol “◯” denotes a conductivity characteristic of the metal nanoparticle ink after the buffer layer is etched, according to the thermal treatment/sintering temperature. Referring to FIG. 3, as the temperature of the thermal treatment/sintering process is increased, the conductivity is improved. Therefore, it is difficult to form the metal lines having high conductivity characteristic by performing direct printing on a film substrate. Therefore, there is required a technique of performing a thermal treatment/sintering process on a substrate having excellent heat resistance and, after that, forming highly-conductive metal lines on a flexible substrate through a transfer process. It can be understood that the conductivity characteristic of the metal lines manufactured according to the present invention is not affected by the wet etching process for etching the buffer layer.

Next, referring to (2) of FIG. 2, the metal lines are picked up by using a flat stamp 230. After the stamp is arranged on the metal lines, a pressure is exerted. Due to the pressure, the supporting members are destructed, and the metal lines are detached from the first substrate, so that the metal lines can be picked up on the stamp. At this time, an elastic stamp having viscoelasticity is needed in order to optimize the pick-up condition. In this case, a pick-up speed of the stamp is set to 100 mm/s.

FIG. 4 is a conceptual cross-sectional diagram illustrating the process of picking up the metal lines by using the flat stamp in the metal line forming method according to the first embodiment of the present invention.

As the stamp, a polymer having elasticity is preferable, and an example, PDMS (polydimethylsiloxane), PUA (polyurethane acrylate), or the like may be used.

Next, the metal lines on the stamp are transfer-printed on a second substrate 250 which is a flexible substrate. One of the two methods illustrated in (e-1) or (e-2) of FIG. 2 may be selectively performed.

In the method according to (e-1) of FIG. 2, an adhesive substance is applied on a surface of the second substrate 250 which is the flexible substrate which is used to manufacture flexible electronic devices to form an adhesive layer 260. After that, the metal lines on the stamp are arranged on the adhesive layer, and the transfer printing is performed.

In the method according to (e-2) of FIG. 2, an adhesive substance is contact-printed on lower surfaces of the metal lines on the stamp to form an adhesive layer 260. After that, the metal lines on the stamp are transfer-printed on a surface of the second substrate 250.

The adhesive substance may be configured with a polymer substance having a strong adhesion force. As the adhesive substance, a thermoset material which is thermally cured at a low temperature such as cellulose ether, a photocurable material, or the like may be used.

In this manner, the adhesive layer configured with a polymer substance having a strong adhesion force is formed between the flexible substrate and the metal lines, so that it is possible to improve a stability of the flexible substrate with respect to bending.

Next, the metal lines are detached from the stamp, so that the metal lines are completely formed on the surface of the second substrate. (f-1) of FIG. 2 illustrates a cross-sectional diagram of the metal lines obtained according to the method illustrated in (e-1) of FIG. 2, and (f-2) of FIG. 2 illustrates a cross-sectional diagram of the metal lines obtained according to the method illustrated in (e-2) of FIG. 2.

The second substrate 250 is a flexible substrate which is used to manufacture flexible electronic devices (Flexible Electronics). Since the thermal treatment/sintering process at a high temperature is not necessarily performed on the substrate, any flexible substrate having low heat resistance such as paper, PET (polyethalene terephthalate), PEN (polyethylene naphthalate), or PC (polycarbonate) may be used.

According to the above-described metal line forming method of the present invention, the highly-conductive metal lines are formed on the flexible substrate having low heat resistance.

### Second Embodiment

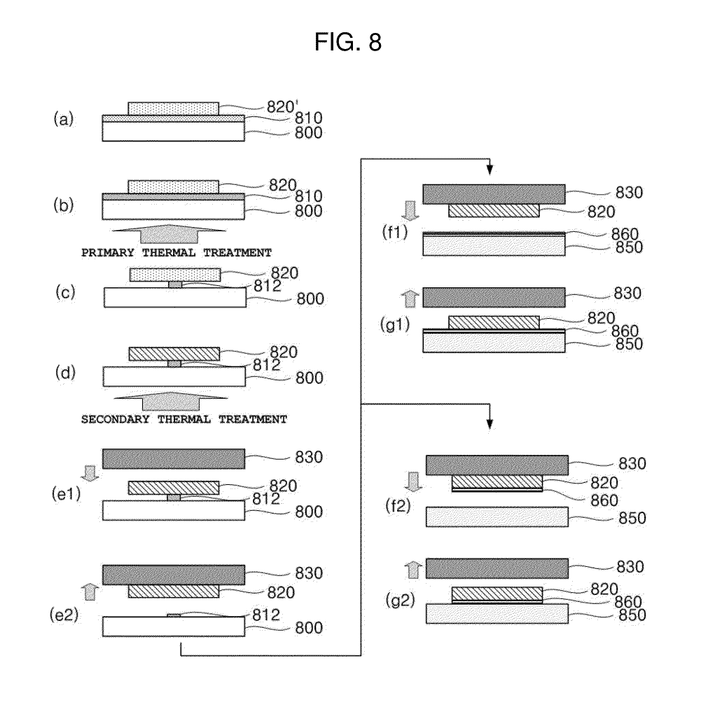

Hereinafter, a metal line forming method according to a second embodiment of the present invention will be described in detail with reference the attached drawings. FIG. 8 is is a diagram illustrating a sequence of processes of the metal line forming method according to the second embodiment of the present invention.

Referring to (a) of FIG. 8, in the metal line forming method according to the second embodiment of the present invention, first, a buffer layer 810 is formed on a first substrate 800 through a printing process, and after that, metal lines are formed by printing a metal nanoparticle ink 820′ over the buffer layer. In the embodiment, the metal nanoparticle ink, the first substrate, and a second substrate are the same as those of the first embodiment. In addition, in the embodiment, a printing process for the metal nanoparticle ink is the same as that of the first embodiment.

The buffer layer 810 may be formed by using a solution having a low viscosity and a low surface tension and containing a material which is processable in a printing process and an additional etching process. The buffer layer may be formed by using, for example, polyimide. Particularly, the buffer layer needs to be configured with a material of which characteristics are not changed at a high temperature or a material of which partial curing is induced so that an additional etching process is available according to a thermal treatment condition. A buffer layer etching solution which is to be used in a process of etching the buffer layer needs to be a solvent which is able to etch the buffer layer without affecting the metal nanoparticle ink. As an example of the above-described condition, in the state where polyimide is used as the buffer layer, a distilled potassium hydroxide (KOH) solvent or the like may be used at the etching solvent.

Next, referring to (b) of FIG. 8, in order to selectively etch the buffer layer in a post process, primary thermal treatment capable of inducing partial curing of the buffer layer is performed. At this time, the temperature condition of the thermal treatment is preferably a temperature range of about 160° C. to 200° C.

Next, referring to (C) of FIG. 8, supporting members are formed by partially etching the buffer layer by wet etching. In this manner, in order to partially etch the buffer layer by wet etching, the entire resulting product is immersed into the buffer layer etching solution, and the wet etching is performed on the buffer layer. At this time, an etching time is controlled so that a portion of the buffer layer is not etched. Due to the non-etched portion of the buffer, the supporting members 812 are formed between the metal lines 820 and the first substrate 800. Therefore, the pattern shape of the metal lines is maintained even after the etching process and a transfer process, and a pick-up process is facilitated.

The buffer layer etching solution needs to be a material which reacts with only the buffer layer so as to etch only the buffer layer without affecting the metal nanoparticle ink. In addition, the buffer layer etching solution needs to be a material which effectively dissolves the buffer layer even after the primary thermal treatment. On the other hand, in the embodiment, in the state where the buffer layer is formed by using polyimide, after the above-described partial curing is induced, the etching process may be performed by using a potassium hydroxide solvent.

Next, referring to (d) of FIG. 8, the metal nanoparticle ink is sintered through secondary thermal treatment at a high temperature, so that the conductivity of the metal lines 820 is improved. The thermal treatment/sintering process is performed at a high temperature of about 200° C. to 300° C.

Next, referring to (e1) and (e2) of FIG. 8, the metal lines are picked up from the first substrate by using a stamp in the state where the pattern of the metal lines is fixed and arranged by the supporting members. Next, referring (f1), (g1), (f2), and (g2), the picked-up metal lines are transferred to the second substrate. The pick-up process and the transfer process on the metal lines are the same as those of the first embodiment.

On the other hand, preferably, a ratio of contact areas between the metal lines and the supporting members are adjusted by controlling the etching condition in the buffer layer etching process for forming the supporting members, so that first adhesion energy by the contact surface between the metal lines and the stamp occurring in the transfer process and second adhesion energy by the contact surfaces between the metal lines and the supporting members are adjusted, and the metal lines are picked up from the first substrate by using the stamp.

### Third Embodiment

Hereinafter, a highly-conductive metal line forming method on a flexible substrate by using a metal nanoparticle ink according to a third embodiment of the present invention will be described in detail. The metal line forming method according to the third embodiment is different from the first and second embodiments where a flat stamp is used. In the third embodiment, a transfer process is performed by using a stamp having a patterned mold, so that metal lines can be selectively picked up from a first substrate according to a shape of the stamp having the patterned mold in transfer printing.

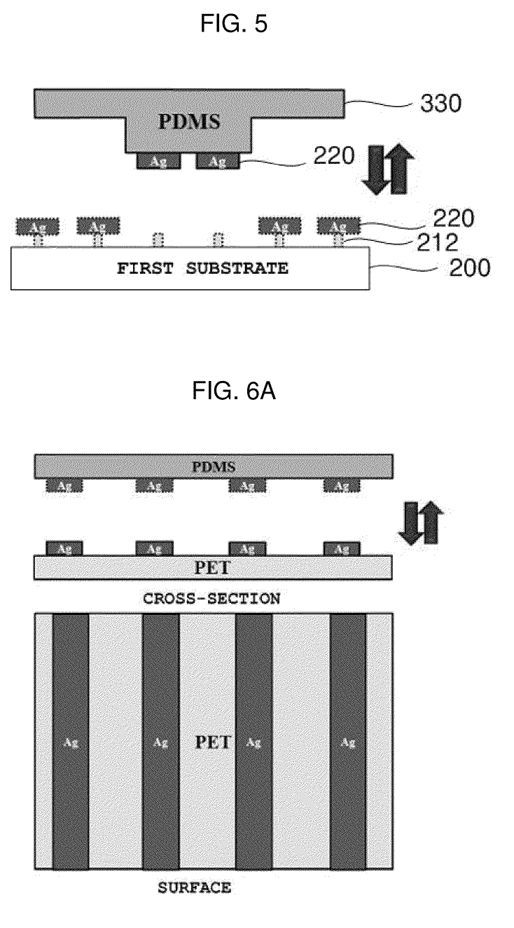

The stamp used in the metal line forming method according to the third embodiment is different from the stamps in the metal line forming method according to the first and second embodiments in terms of a shape. FIG. 5 is conceptual cross-sectional diagram illustrating a pick-up process using the stamp 330 having the patterned mold in the metal line forming method according to the third embodiment of the present invention.

As illustrated in FIG. 5, in the metal line forming method according to the third embodiment, the metal lines can be selectively picked up and be transfer-printed according to a pattern of the stamp. In other words, in the case of using the stamp 33 having the patterned mold according to the embodiment, the picking-up and printing are performed only in the portion where the metal lines and the stamp are in contact with each other.

On the other hand, as illustrated in FIG. 4, in the metal line forming method according to the first embodiment, in the case of using the flat stamp, since the entire area of the stamp is in contact with the metal lines, all the portions are picked up, and the printing is performed.

In the above-described metal line forming method according to the present invention, the metal lines are transfer-printed by using the stamp, so that it is possible to repetitively perform the transfer printing by using the stamp, and the printing direction is controlled, so that it is possible to implement a stack structure and a mesh structure.

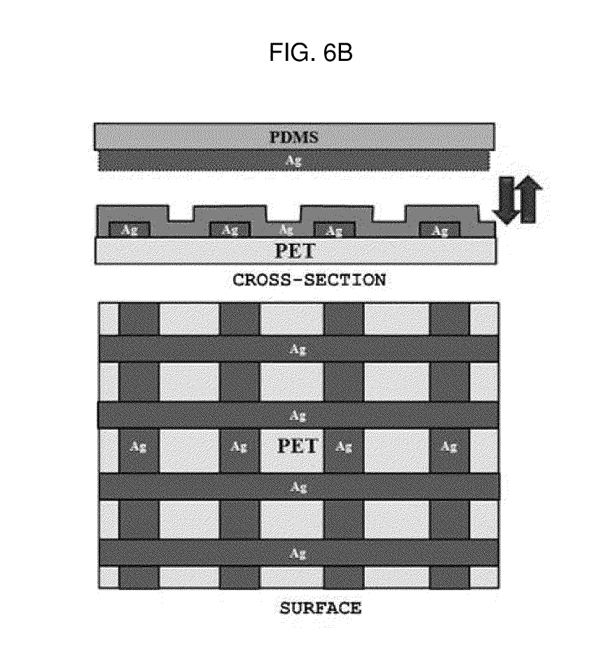

FIGS. 6A and 6B are cross-sectional diagrams and plan diagrams illustrating a mesh-shaped stack structure which formed by repetitively performing the transfer printing by using the stamp while changing the printing direction by 90 degrees in the metal line forming method according to the present invention. FIG. 6A is a cross-sectional diagram and a plan diagram illustrating a result obtained by performing first transfer printing, and FIG. 6B is a cross-sectional diagram and a plan diagram illustrating a result obtained by performing second transfer printing on the substrate which is subjected to the first transfer printing in the vertical direction. As illustrated in FIG. 6, the transfer printing is repetitively performed while changing the direction of the stamp, so that it is possible to form the metal lines having a mesh-shaped stack structure. Therefore, a transparent surface electrode element having low sheet resistance and high transmittance can be formed.

In general, when metal lines are formed, as a width of a line electrode is narrowed, transmittance of light is increased. Particularly, in the case of forming metal lines in a mesh-shaped electrode structure, if an interval between the metal lines is finely controlled, the characteristic is obtained that the surface resistance is the same as that of the “surface electrode” obtained by forming the electrode on the entire surface. Therefore, in the case of forming fine metal lines in a mesh shape according to the present invention, it is possible to manufacture a transparent electrode element having an excellent transmittance characteristic and an excellent surface resistance characteristic due to the highly-conductive metal lines formed by using a thermal treatment/sintering process.

On the other hand, in the case of forming a functional element, a thin film, or the like on a flexible substrate, it is important to secure stability according to bending of the substrate. At this time, in the case of the thin film formed on the flexible substrate, if a bending stress is exerted, crack occurs in the thin film, or the thin film is peeled off from the flexible substrate. Since a cross-linking agent is added to the metal nanoparticle ink, the pick-up process is not easily performed on the metal nanoparticle ink due to a strong adhesion force between the thin film of the metal lines and the substrate. In order to solve this problem, a buffer layer is formed, and the pick-up process is performed. In this case, since the characteristic of the adhesion force by the cross-linking agent disappears, the crack can be reduced, but the peeling-off of the thin film does still exist.

In order to solve this problem, in the metal line forming method according to the present invention, an adhesive layer is added between the flexible substrate and the metal lines, so that the peeling-off of the metal lines due to the bending is prevented. Therefore, it is possible to improve the stability with respect to the bending.

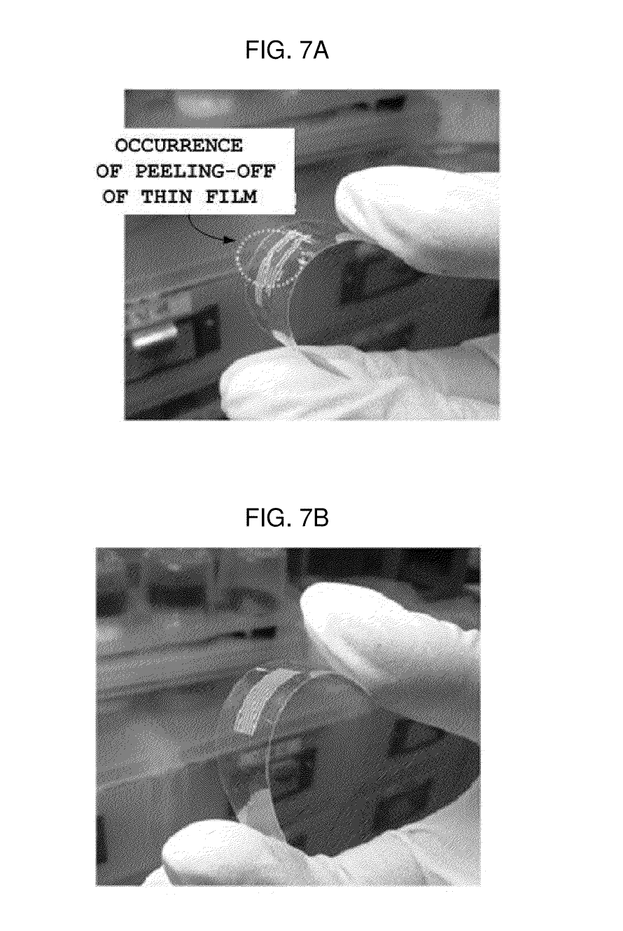

FIGS. 7A and 7B are pictures of test of stability with respect to the bending according to the existence of the adhesive layer in the metal line forming method according to the present invention. As the conditions of the test of FIGS. 7A and 7B, a Bending radius is set to 2 cm, and the number of times of bending is 10000.

FIG. 7A illustrates the case where the adhesive layer is not formed, and it can be easily observed that the peeling-off of the thin film occurs when the flexible substrate is bent. FIG. 7B illustrates the case where the adhesive layer is formed, and it can be observed that the peeling-off of the thin film does not occur even though the flexible substrate is bent.

According to the above-described the present invention, the highly-conductive metal lines can be formed on the flexible substrate by using the metal nanoparticle ink through the transfer printing process.

Hereinafter, in the above-described metal line forming methods according to the first to third embodiments, the process of picking up the metal lines from the first substrate by using the stamp will be described in detail.

The condition of Mathematical Formula 1 needs to be satisfied in order to pick up the metal lines from the first substrate by using the stamp.

(First Adhesion Energy×Stamp Pick-up speed)>Second Adhesion Energy [Mathematical Formula 1]

Herein, the first adhesion energy is adhesion energy on the contact surface between the stamp and the metal lines, the second adhesion energy is adhesion energy on the contact surface between the metal lines and the supporting members, and the stamp pick-up speed is a speed of picking up the stamp which is in contact with the metal lines. Therefore, the pick-up yield can be determined according to the first adhesion energy, the second adhesion energy, and the stamp pick-up speed.

Since the first adhesion energy is mainly determined according to the contact area between the stamp and the metal lines, the first adhesion energy is determined according to the line width of the metal lines. On the other than, since the second adhesion energy is mainly determined according to the contact area between the metal lines and the supporting members and the area of the metal lines is a fixed value according to the line width of, the second adhesion energy is determined according to the area of the supporting members.

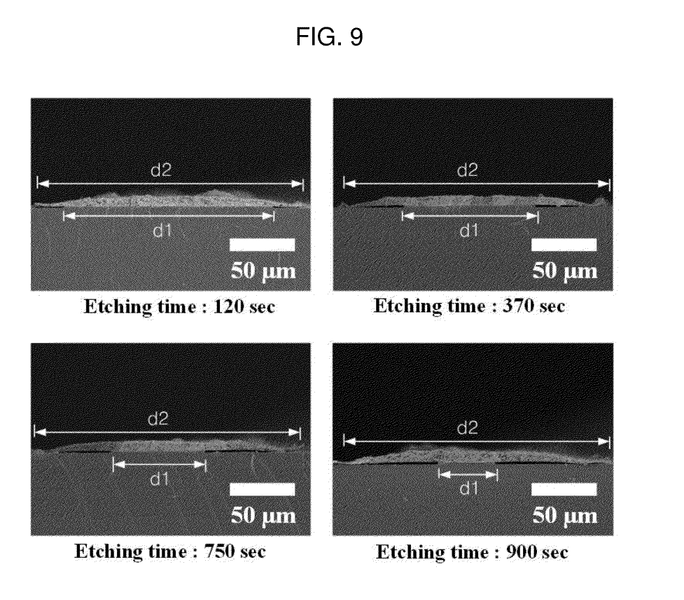

FIG. 9 is pictures illustrating a change of the supporting members according to the etching time with respect to the buffer layer and the contact area between the metal lines and the supporting members in the metal line forming method according to the present invention. Referring to FIG. 9, (a), (b), (c), and (d) illustrate the cases of the etching time being 120 seconds, 370 seconds, 750 seconds, and 900 seconds. It can be observed that, as the etching time is increased, the width of the supporting member is decreased, and as a result, the contact area between the metal lines and the supporting members is decreased. In FIG. 9, the width of the metal line is d2, and the width of the supporting member is d1.

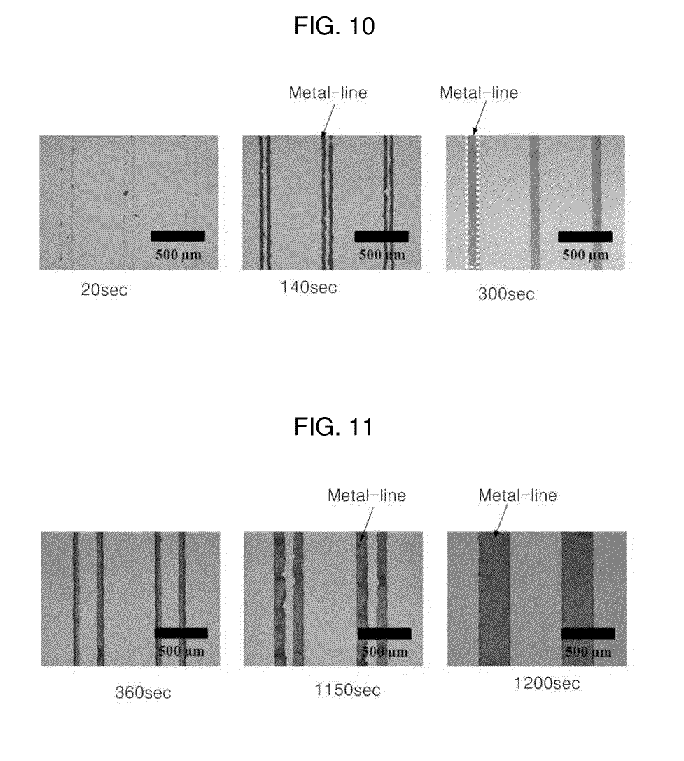

FIGS. 10 and 11 are diagrams illustrating pictures of the surface of the stamp on which the metal lines are picked up for explaining the pick-up yield according to the buffer layer etching times of the metal lines having different line widths in the metal line forming method according to the present invention.

Referring to FIG. 10, in the metal lines having a line width of 100 μm, the pick-up state of the stamp can be seen in the cases where the buffer layer etching time is 20 seconds, 140 seconds, and 300 seconds. In the state where the buffer layer etching time is 20 seconds, the metal lines are hardly picked up. In the state where the buffer layer etching time is 140 seconds, the metal lines are incompletely picked up. In the state where the buffer layer etching time is 300 seconds, the metal lines are completely picked up.

Referring to FIG. 11, in the metal lines having a line width of 300 μm, the pick-up state of the stamp can be seen in the cases where the buffer layer etching time is 360 seconds, 1150 seconds, and 1200 seconds. In the buffer layer etching time is 360 seconds, the metal lines are hardly picked up. In the state where the buffer layer etching time is 1150 seconds, the metal lines are incompletely picked up. In the state where the buffer layer etching time is 1200 seconds, the metal lines are completely picked up.

Referring to FIGS. 10 and 11, the optimal buffer layer etching conditions required for achieving 100% transfer yield of the metal lines are different according to the line width of the metal lines. In addition, it can be understood that, as the line width of the metal line is increased, the line width of the supporting member occurring after the etching of the buffer layer in the case of 100% picking up is increased, and the ratio of the line widths between the metal lines and the supporting members at the 100% pick-up condition is the same. In other words, it can be understood that, the absolute line width of the supporting member formed by the etching at the time of achieving 100% pick-up yield is not important, but the ratio of the line widths (areas) between the metal lines and the supporting members is important. In addition, it can be understood that the optimization is needed.

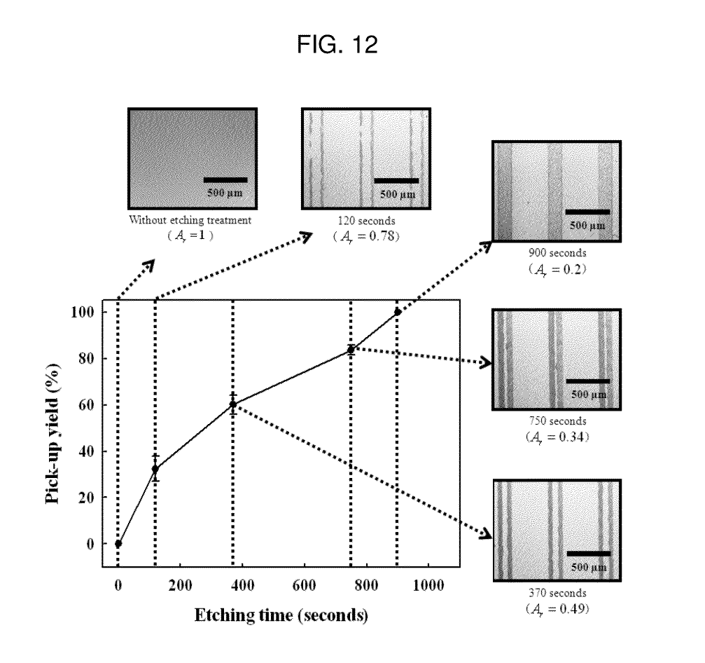

FIG. 12 is a graph illustrating a pick-up yield of the metal lines according to the buffer layer etching time in the metal line forming method according to the present invention. In FIG. 11, Ar denotes a value indicating the ratio of (contact area between the metal lines and the supporting members)/(contact area between the metal lines and the stamp). Referring to FIG. 12, as the etching time is increased, the value Ar is decreased, and as the value Ar is decreased, the contact area between the metal lines and the supporting members is decreased, so that the pick-up yield is increased. In other words, as the contact area between the metal lines and the supporting members is decreased, the adhesion energy of the metal lines and the supporting members is decreased, so that the relationship expressed by Mathematical Formula 1 is satisfied, and the metal lines are picked up from the supporting members to the stamp.

Therefore, in order to optimize the transfer condition, preferably, the contact area between the metal lines and the supporting members is adjusted by controlling the buffer layer etching condition, so that the first adhesion energy of the stamp and the metal lines and the second adhesion energy of the metal lines and the supporting members are adjusted, and the metal lines are picked up.

While the present invention has been particularly shown and described with reference to exemplary embodiments thereof, it will be understood by those skilled in the art that various changes in form and details may be made therein without departing from the spirit and scope of the invention as defined by the appended claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

The method according to the present invention can be widely used for a method of manufacturing a flexible electronic devices (flexible electronics) using a flexible substrate. Particularly, the method according to the present invention can be used for the case of forming highly-conductive metal lines on a flexible substrate by using a metal nanoparticle ink.

What is claimed is:

1. A method of forming metal lines having high conductivity on a flexible substrate, comprising:
(a) forming a buffer layer on a first substrate;
(b) forming metal lines by printing a metal nanoparticle ink on a surface of the buffer layer;
(c) sintering the metal nanoparticle ink through thermal treatment to improve the conductivity of the metal lines;
(d) forming supporting members between the metal lines and the first substrate by etching the buffer layer by using a buffer layer etching solvent and by controlling an etching time so that a portion of the buffer layer is not etched;
(e) picking up the metal lines from the first substrate by using a stamp in the state where a pattern of the metal lines is fixed and arranged by the supporting members; and
(f) transferring the picked-up metal lines to a second substrate,
wherein the first substrate is a heat resistant substrate which is not deformed at a sintering temperature of the metal nanoparticle ink, and the second substrate is a flexible substrate.

2. The method according to claim 1,
wherein the (f) transferring the picked-up metal lines includes:
(f1) forming an adhesive layer by applying an adhesive substance on the entire surface of the second substrate;
(f2) arranging the metal lines picked up by stamp on a surface of the adhesive layer by adhering the metal lines on the adhesive later; and
(f3) detaching the stamp from the metal lines to transfer the metal lines to the second substrate, and
wherein the metal lines are transfer-printed on the second substrate through the adhesive layer.

3. The method according to claim 1,
wherein the (f) transferring the picked-up metal lines includes:
(f1) forming an adhesive layer on a surface of the metal lines picked up by the stamp by contact-printing the stamp picking up the metal lines on an adhesive substance;
(f2) arranging the stamp on which the adhesive layer is formed on the second substrate; and
(f3) detaching the stamp from the metal lines to transfer the metal lines to the second substrate, and
wherein the metal lines are transfer-printed on the second substrate through the adhesive layer.

4. The method according to claim 1, wherein the (e) picking up the metal lines from the first substrate includes:
(e1) destructing the supporting members by applying a pressure by which the supporting members are able to be destructed by the stamp in the state where a pattern of the metal lines is arranged and retained by the supporting members; and
(e2) picking up the metal lines detached from the supporting members due to the destruction of the supporting members by using the stamp.

5. The method according to claim 1, wherein the stamp is configured with a flat stamp or a stamp having a patterned mold.

6. The method according to claim 1, wherein the buffer layer etching solvent is configured with a material which does not affect the metal lines.

7. The method according to claim 1, wherein the stamp is configured with an elastic polymer substance.

8. The method according to claim 1, wherein the metal nanoparticle ink is configured by dispersing metal nanoparticles of which surfaces are coated with a dispersant into a solvent, and the metal nanoparticle ink is allowed to have a high conductivity characteristic through a thermal treatment/sintering process.

9. The method according to claim 1, wherein the stamp is configured with a stamp having a patterned mold, and a mesh structure of the metal lines is formed by repetitively performing the (e) picking up the metal lines and the (f) transferring the picked-up metal lines.

10. The method according to claim 1, wherein the buffer layer is configured with an organic material having low viscosity and low surface tension so as to allow a surface of the first substrate to be coated or a material of which partial curing is induced according to a thermal treatment condition.

11. A method of forming metal lines having high conductivity on a flexible substrate, comprising:
(a) forming a buffer layer on a first substrate;
(b) forming metal lines by printing a metal nanoparticle ink on a surface of the buffer layer;
(c) partially curing the buffer layer through primary thermal treatment;
(d) forming supporting members between the metal lines and the first substrate by etching the buffer layer by using a buffer layer etching solvent and by controlling an etching time so that a portion of the buffer layer is not etched;
(e) sintering the metal nanoparticle ink through secondary thermal treatment to improve the conductivity of the metal lines;
(f) picking up the metal lines from the first substrate by using a stamp in the state where a pattern of the metal lines is fixed and arranged by the supporting members; and
(g) transferring the picked-up metal lines to a second substrate,
wherein the first substrate is a heat resistant substrate which is not deformed at a sintering temperature of the metal nanoparticle ink, and the second substrate is a flexible substrate.

12. The method according to claim 11,
wherein the (g) transferring the picked-up metal lines includes:
(g1) forming an adhesive layer by applying an adhesive substance on the entire surface of the second substrate;
(g2) arranging the metal lines picked up by the stamp on a surface of the adhesive layer and adhering the metal lines to the surface of the adhesive layer; and
(g3) detaching the stamp from the metal lines to transfer the metal lines to the second substrate, and
wherein the metal lines are transfer-printed on the second substrate through the adhesive layer.

13. The method according to claim 11,
wherein the (g) transferring the picked-up metal lines includes:
(g1) forming an adhesive layer between the surfaces of the metal lines and the stamp by contact-printing the stamp which picks up the metal lines on an adhesive substance;
(g2) arranging the stamp where the adhesive layer is formed on the second substrate and adhering the stamp to the second substrate; and
(g3) detaching the stamp from the metal lines to transfer the metal lines to the second substrate, and
wherein the metal lines are transfer-printed on the second substrate through the adhesive layer.

14. The method according to claim 11, wherein the (f) picking up the metal lines includes:
(f1) adjusting first adhesion energy according to a contact surface of the stamp and the metal lines and second adhesion energy according to a contact surface between the metal lines and the supporting members; and
(f2) picking up the metal lines from the first substrate by using the stamp.

15. The method according to claim 11, wherein the stamp is configured with a flat stamp or a stamp having a patterned mold.

16. The method according to claim 11, wherein the buffer layer etching solvent is configured with a material which does not affect the metal lines.

17. The method according to claim 11, the stamp is configured with an elastic polymer substance.

18. The method according to claim 11, wherein the metal nanoparticle ink is configured by dispersing metal nanoparticles of which surfaces are coated with a dispersant into a solvent, and the metal nanoparticle ink is allowed to have a high conductivity characteristic through a thermal treatment/sintering process.

19. The method according to claim 11, wherein the stamp is configured with a stamp having a patterned mold, and a mesh structure of the metal lines is formed by repetitively performing the (f) picking up the metal lines and the (g) transferring the picked-up metal lines.

20. The method according to claim 11, wherein the buffer layer is configured with an organic material having low viscosity and low surface tension so as to allow a surface of the first substrate to be coated or a material of which partial curing is induced according to a thermal treatment condition.
